(19) United States
(12) Patent Application Publication
(10) Pub. No.: US 2011/0037137 A1
(43) Pub. Date: Feb. 17, 2011

(54) BACK-SIDE ILLUMINATED IMAGE SENSOR PROTECTED AGAINST INFRARED RAYS

(75) Inventor: Hélène Wehbe-Alause, Grenoble (FR)

Correspondence Address: STMicroelectronics Inc.;c/o WOLF, GREENFIELD & SACKS, P.C., 600 Atlantic Avenue, BOSTON, MA, 02210-2206, US

(73) Assignee: STMicroelectronics S.A., Montrouge (FR)

(21) Appl. No.: 12/851,887

(22) Filed: Aug. 6, 2010

(30) Foreign Application Priority Data
Aug. 12, 2009 (FR) 09/55635

(51) Int. Cl. H01L 31/0216; H01L 31/18

(52) U.S. Cl. 257/434; 438/64; 257/E31.119

(57) ABSTRACT

An image sensor including a first substrate having a first surface intended to be illuminated and a second surface on the side of which is formed a plurality of photodetection areas, said second surface being covered with a stack of interconnect levels including metal layers topped with insulating material, and of a second substrate placed on the insulating material of the last interconnect level, in which are formed vias in contact with connection elements of the interconnect levels, at least one of the interconnect levels including conductive shielding areas aligned with the photodetection areas.

### CROSS REFERENCE TO RELATED APPLICATIONS

This application claims the priority benefit of French patent application Ser. No. 09/55635, filed on Aug. 12, 2009, entitled “BACK-SIDE ILLUMINATED IMAGE SENSOR PROTECTED AGAINST INFRARED RAYS,” which is hereby incorporated by reference to the maximum extent allowable by law.

### BACKGROUND OF THE INVENTION

1. Field of the Invention

The present invention relates to a back-side illuminated image sensor and, more specifically, to a back-side illuminated image sensor comprising elements enabling to avoid the detection of parasitic infrared rays.

2. Discussion of the Related Art

A continuing concern in the manufacturing of image sensors formed on semiconductor substrates is to avoid the detection of parasitic light beams. Especially, when a color image sensor is desired to be formed for visible light, that is, to be sensitive to the same radiations as the human eye, the influence of infrared rays is desired to be avoided.

It is thus necessary to provide elements for avoiding the detection of infrared light beams. For this purpose, on the sensor side intended to be illuminated, elements, for example, a resin plate, are generally provided to filter infrared rays.

On the side of the structure which is not illuminated, devices forming a contact with photodetection elements, for example, solder bumps, are generally provided. Thus, the device is slightly distant from the support on which it will be subsequently attached. Parasitic infrared rays may penetrate through the non-illuminated surface to reach the semiconductor substrate. Indeed, in semiconductor materials, and especially in silicon, incident infrared rays cause the forming of electron/hole pairs deep inside of the silicon. Thus, infrared beams may be detected in photodetection areas distant from penetration point of the beam in the substrate. To avoid a parasitic detection of these rays, a conventional technique comprises forming, on the non-illuminated side, a black resin layer blocking these rays and any other ray.

To form such a structure, a black resin layer is deposited over the entire surface to be protected, after which openings are defined in this resin layer. Solder bumps are then formed in these openings. Thus, the obtaining of a black resin layer means carrying out additional manufacturing steps with respect to already very complex conventional methods for forming image sensors. One of the limitations of this resin layer is its thickness variations at locations where it is crossed by rear surface connection routings, which thus makes its efficiency fluctuate locally. Another negative interaction occurs with metal bonding pads which are generally provided, before the forming of the solder bumps: the black resin must be removed above the bonding pads to enable the forming of an intermetallic compound between the pad and the bump. However, the resin residue at these locations will tend to limit the forming of intermetallic compounds, thus deteriorating both the electric contact and the mechanical hold of the package when it is only maintained by the bumps.

Further, black resin is relatively expensive if it is needed over a significant surface area, that is, over an entire semiconductor material wafer. Such resins also have the disadvantage of being relatively fragile. Thus, during assembly steps of the image sensor, the resin may be scratched or cracked, which makes it lose its advantages and creates at the front surface of such defects ghost images in the form of points.

Thus, there is a need for an image sensor comprising elements, other than a black resin layer, capable of attenuating the detection of parasitic infrared light beams.

### SUMMARY OF THE INVENTION

An object of an embodiment of the present invention is to provide a back-side illuminated image sensor comprising elements enabling to avoid the detection of parasitic infrared light beams.

Another object of an embodiment of the present invention is to provide a method for manufacturing such an image sensor which requires no additional steps with respect to conventional manufacturing methods.

An embodiment of the present invention provides an image sensor comprising a first substrate having a first surface intended to be illuminated and a second surface on the side of which is formed a plurality of photodetection areas, said second surface being covered with a stack of interconnect levels comprising metal layers topped with insulating material, and of a second substrate placed on the insulating material of the last interconnect level, in which are formed vias in contact with connection elements of the interconnect levels, at least one of the interconnect levels comprising conductive shielding areas aligned with the photodetection areas.

According to an embodiment of the present invention, the conductive shielding areas comprise a large conductive track formed aligned with the photodetection areas in an interconnect level.

According to an embodiment of the present invention, the conductive shielding areas comprise a first assembly of parallel conductive tracks formed in a first interconnect level and a second assembly of parallel conductive tracks formed in a second interconnect level, the conductive tracks of the first and second assemblies being mutually perpendicular.

According to an embodiment of the present invention, the image sensor further comprises, on the free side of the second substrate and on the vias, solder bumps.

According to an embodiment of the present invention, the image sensor further comprises a glass plate formed on the first surface of the first substrate.

According to an embodiment of the present invention, the first and second substrates are made of silicon and have a thickness ranging between 60 and 80 μm.

An embodiment of the present invention provides a method for forming a back-side illuminated image sensor, comprising the steps of forming, in and on a semiconductor substrate, photodetection elements topped with interconnect levels comprising metal layers topped with insulating material; forming, in at least one interconnect level, conductive shielding areas aligned with photodetection areas of the photodetection elements; placing a second semiconductor substrate on the insulating material of the last interconnect level and thinning down the first substrate; placing a glass plate on the surface of the first thinned-down substrate opposite to the last interconnect level and thinning down the second substrate; and forming vias in the second substrate.

The foregoing objects, features, and advantages of the present invention will be discussed in detail in the following non-limiting description of specific embodiments in connection with the accompanying drawings.

### BRIEF DESCRIPTION OF THE DRAWINGS

FIGS. 1A to 1E illustrate results of steps of a method for forming an image sensor according to an embodiment of the present invention;

FIG. 2 is a simplified three-dimensional diagram illustrating a first example of an image sensor according to an embodiment of the present invention; and

FIG. 3 is a simplified perspective view of a second example of an image sensor according to an embodiment of the present invention.

### DETAILED DESCRIPTION

For clarity, the same elements have been designated with the same reference numerals in the different drawings and, further, as usual in the representation of image sensors, the various drawings are not to scale.

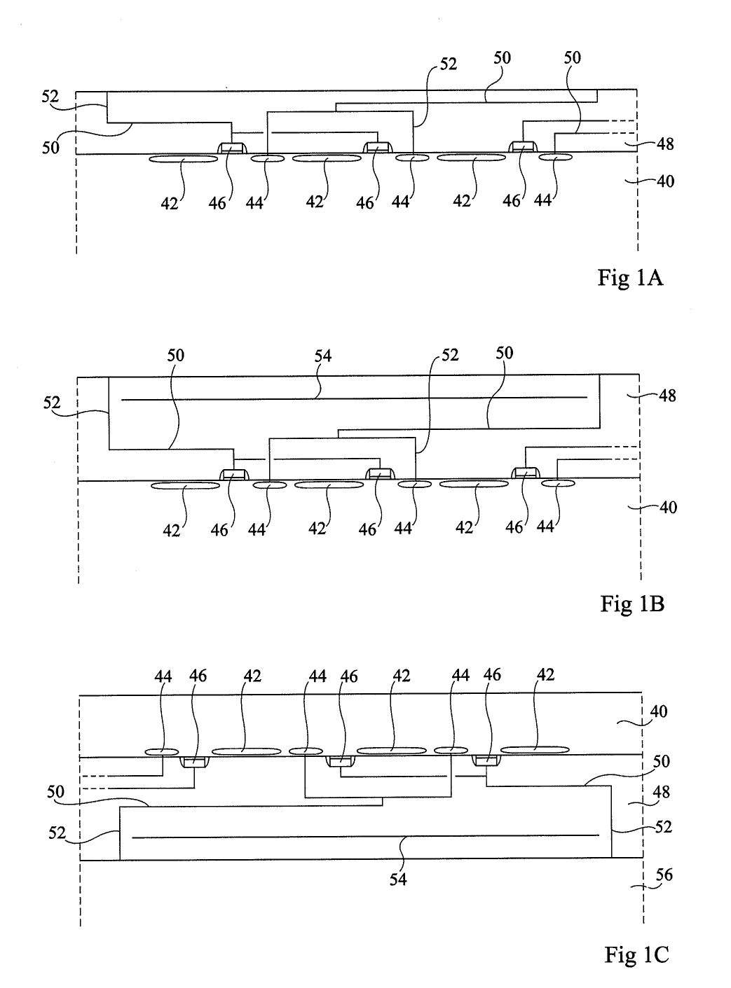

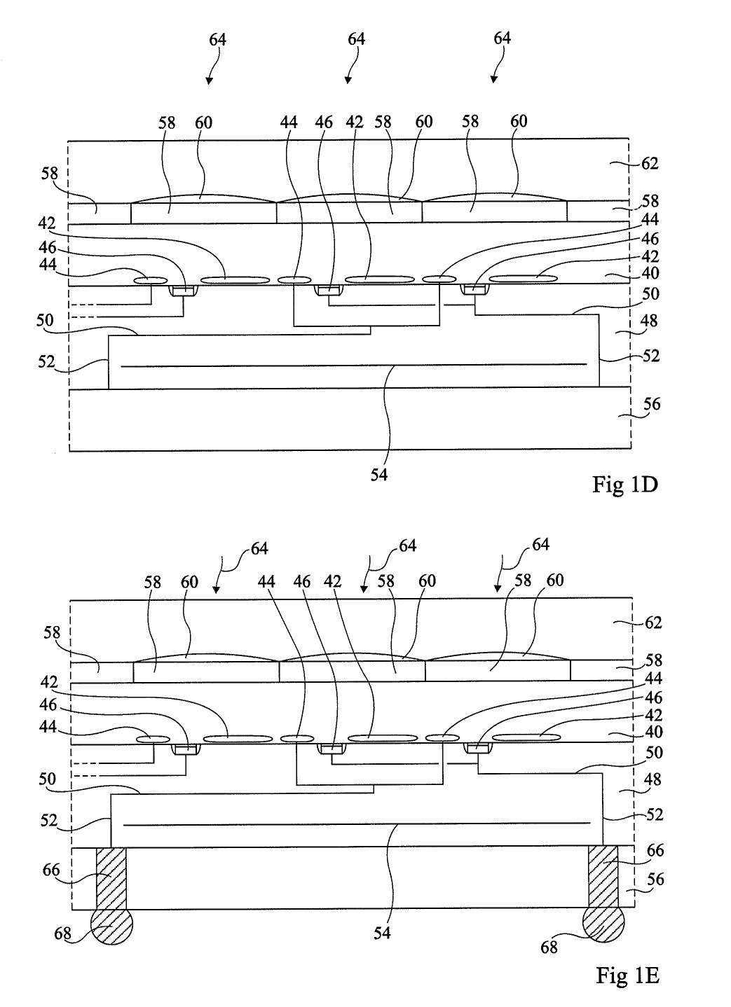

FIGS. 1A to 1E illustrate results of steps of a method for manufacturing a back-side illuminated image sensor.

At the step illustrated in FIG. 1A, image photodetection elements, for example, photodetection areas 42 and areas of transfer of the photogenerated charges 44 and transfer and charge reading transistors 46, have been formed in and on a semiconductor substrate 40, for example made of silicon. It should be noted that other elements may be formed in and on top of substrate 40.

An interconnect stack 48 in which tracks 50 and vias 52 enabling to connect the different photodetection elements together and to the outside of the device are formed covers the entire structure. Each interconnect level is topped by a dielectric layer, thereby avoiding short-circuits in the interconnect stack. Contacts to the outside of the device are provided on the upper surface of interconnect stack 48. It should be noted that, conventionally, the contacts to the outside of the device are off-centered from the photodetection areas.

At the step illustrated in FIG. 1B, interconnect stack 48 has been completed with upper levels. A conductive area 54 substantially covering the entire photodetection area is formed in one or several upper interconnect levels of interconnect stack 48.

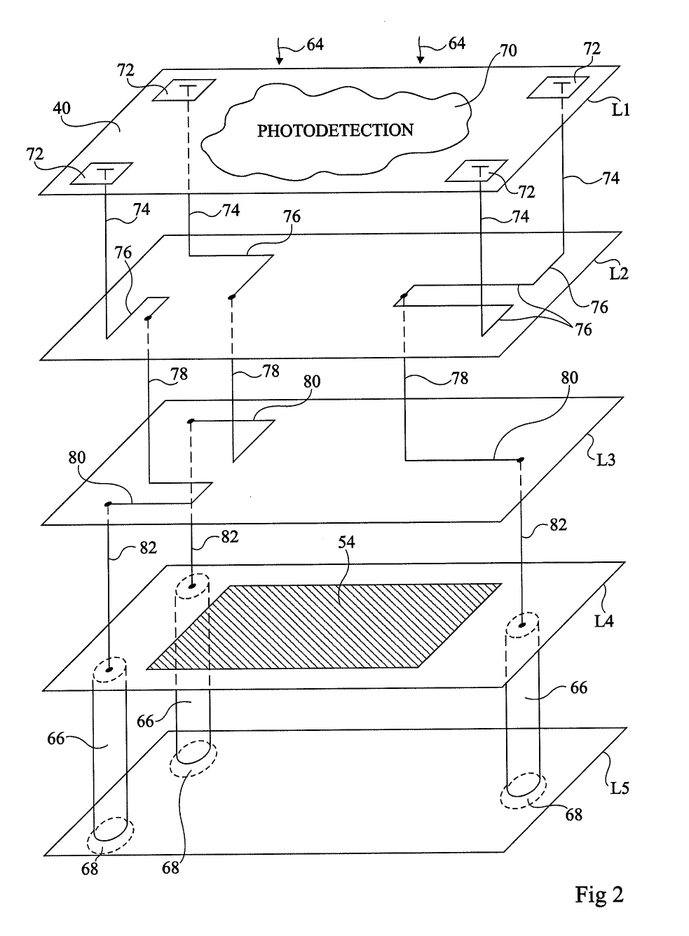

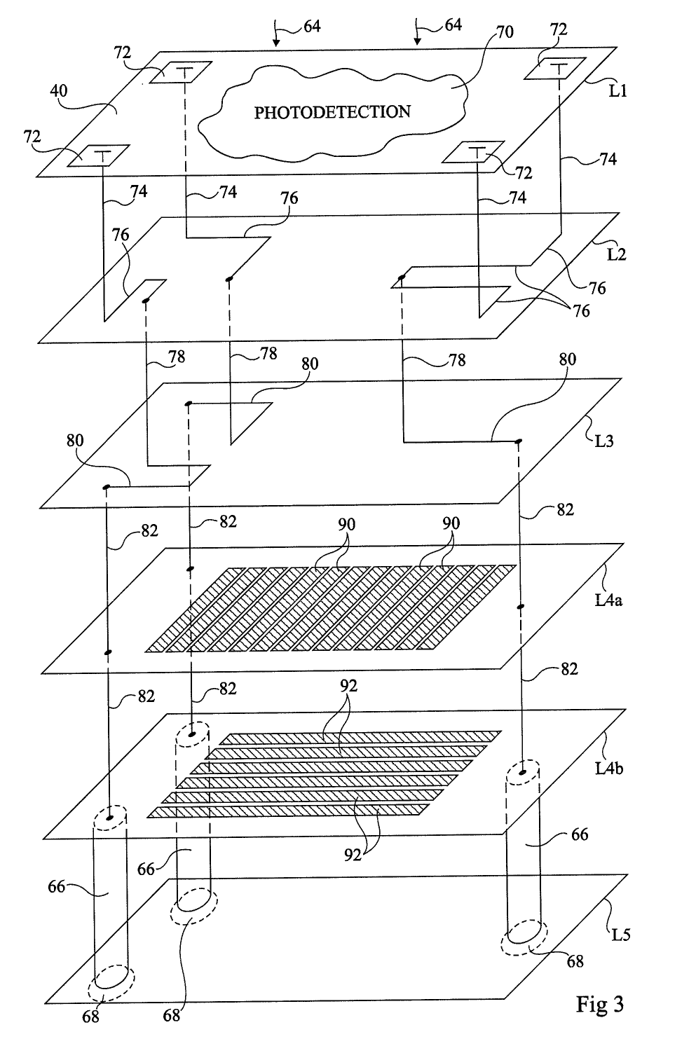

In FIG. 1B and in FIGS. 1C to 1E, a single area 54 extending over the entire surface aligned with the photodetection area has been shown. As will be seen hereafter in relation with FIGS. 2 and 3, various structures forming area 54 are possible. Moreover, area 54 can also be placed at any interconnect level, for example in one of the first interconnect levels.

Conductive area 54 provides a shield function for blocking infrared rays arriving on the front surface of the device, as will be seen hereafter. Advantageously, the forming of conductive area 54 does not need any additional steps with respect to conventional methods for manufacturing back-side illuminated image sensors since, in such methods, tracks are formed in the interconnect levels, especially to connect image processing elements arranged at the periphery of the photodetection area. Thus, the addition of conductive region 54 only needs a modification of the mask(s) used in the manufacturing of one or several interconnect levels.

At the step illustrated in FIG. 1C, a semiconductor substrate 56, for example, made of silicon, has been formed on interconnect stack 48. The device is then flipped and substrate 40 is thinned down to have a thickness ranging between 60 and 80 μm, for example, approximately 70 μm with current technologies, but maybe less.

It should be noted that the steps of mounting a semiconductor substrate on the insulating material covering the last level of the interconnect stack and of thinning down of a semiconductor substrate are conventional steps of methods for forming back-side illuminated image sensors. Thus, these steps will not be described in further detail herein. It should also be noted that the step of mounting a semiconductor substrate, for example using a thin dielectric layer formed on the substrate, on the upper insulating layer of a device, provides a better result that techniques in which the semiconductor substrate is mounted via metallic layers of the device and substrate.

At the step illustrated in FIG. 1D and in the case of a color image sensor, color filters 58 have been formed on substrate 40. Microlenses 60 are then formed on the color filers. A thick glass plate 62 is placed on top of the stacking of color filters 58 and of microlenses 60. Glass plate 62 stiffens the device while being transparent to visible light rays arriving on the rear surface of the device (arrow 64) and blocking any infrared radiation.

Second substrate 56 is then thinned down to have a thickness preferably ranging between 60 and 80 μm, for example, 70 μm. This thickness is provided to enable to simply form vias crossing substrate 56 (TSV).

At the step illustrated in FIG. 1E, vias 66 have been formed through substrate 56. Vias 66 are provided to connect vias 52 of interconnect stack 48 to the outside of the device. Then, solder bumps 68 are formed on the front surface of the device to enable its assembly, for example, on a printed circuit wafer.

Thus, advantageously, a device in which parasitic infrared light beams arriving on the front surface (lower surface in FIG. 1E) of the device are stopped by conductive area 54 formed in interconnect stack 48, which area will also be called shielding area hereafter, is obtained. Further, the method described herein has the advantage of requiring no additional steps with respect to a conventional method for forming a back-side illuminated image sensor, since more interconnect levels are generally needed in the logic portion than in the pixel array area and some of these levels are thus unused in the optical portion of the device.

Several solutions are possible to form shielding area 54. FIGS. 2 and 3 are very simplified perspective views illustrating the two examples of forming of conductive shielding area 54. FIGS. 2 and 3 show parallel levels extending in the device.

In the simplified representation of FIG. 2, a first level L1 comprises all the photodetection elements of the device and substantially corresponds to semiconductor substrate 40. This level comprises a photodetection area 70 intended to receive light beams 64 and transfer areas 72, for example, transistors T.

In the shown example, two interconnect levels L2 and L3 are intended to receive interconnect tracks of the image detection elements. Vias 74 are formed between levels L1 and L2, tracks 76 are formed on level L2, vias 78 are formed between level L2 and L3, and tracks 80 are formed on level L3. Two or three levels are generally sufficient to form the interconnections between the various photodetection elements. Thus, the last interconnect levels are not used to connect photodetection elements together and these last levels are crossed by vertical vias 82 all the way to the last interconnect level.

In the example of FIG. 2, on a level L4 forming for example one of the last interconnect levels of the interconnect stack, a conductive area 54, for example, made of copper, is formed aligned with photodetection area 70 of level L1. In the case of FIG. 2, a single conductive plate aligned with the entire photodetection surface forms the shielding against infrared rays. Advantageously, the formation of the shielding areas only aligned with each photodetection area, and not across the whole surface available in level L4, helps prevent a bending phenomenon of the device, which could result from forming large conductive areas. Advantageously, the shielding areas are formed during the same steps as the formation of conductive tracks in the same level, for example by metal deposition followed by chemical mechanical polishing.

A last interconnect level L5 of the structure supports solder bumps 68. Vias 66 crossing the substrate are formed between levels L4 and L5 (in substrate 56 of the previous drawings).

In the variation of FIG. 3, the first three levels of structure L1 to L3 are identical to those of FIG. 2. Level L4 is replaced with two interconnect levels L4a and L4b which are crossed by vertical vias 82 of connection of the photodetection elements to the outside of the device. Aligned with photodetection area 70 of level L1, on level L4a, are formed parallel conductive tracks 90. Tracks 90 extend over a surface in front of the photodetection area of each photodetection element and cover a large portion of this surface (the width of tracks 90 is preferably greater than the space between each of these tracks).

Parallel tracks 92 extending in front of photodetection area 70, but perpendicular to conductive tracks 90 of level L4a are formed on level L4b. As an example, tracks 90 and 92 may be made of copper or of any material conventionally used to formed conductive interconnect tracks, for example, aluminum, tungsten.

Thus, infrared light beams arriving on the lower surface of the device (on the side of level L5) are blocked either by conductive tracks 92, or by conductive tracks 90. It should be noted that the dimensions of tracks 90 and 92 will be easily defined by those skilled in the art to efficiently block such light beams.

It should be noted that the variation of FIG. 3 has the advantage of only forming conventional conductive tracks (with a width similar to that of the interconnect tracks) in levels L4a and L4b. Indeed, although this is possible, it is more difficult to deposit an extensive conductive surface 54, as in the case of FIG. 2, than tracks such as tracks 90 and 92, the deposition of an extensive conductive layer 54 being likely to imply complex planarization steps.

Specific embodiments of the present invention have been described. Various alterations and modifications will occur to those skilled in the art. In particular, it should be noted that the shape of the conductive shielding layer shown in FIGS. 2 and 3 is not limiting. Indeed, other shapes of conductive tracks 90 and 92 may be provided in two interconnect levels or in more than two interconnect levels to form the shielding against infrared rays. It may especially be provided to form conductive tracks in three or four interconnect levels according to specific patterns, for example, interlocked, aligned with photodetection area 70.

The shielding areas could alternatively be formed as close as possible to the photodetection areas, i.e. in the first, second, third and/or fourth interconnect levels, if possible, for example if the interconnections between different elements of the photodetection areas do not use the whole surface of the interconnect level. The formation of shielding areas as close as possible to the photodetection areas allows any parasite rays coming from the front side of the device to be blocked.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. An image sensor comprising a first substrate having a first surface intended to be illuminated and a second surface on the side of which is formed a plurality of photodetection areas, said second surface being covered with a stack of interconnect levels comprising metal layers topped with insulating material, and of a second substrate placed on the insulating material of the last interconnect level, in which are formed vias in contact with connection elements of the interconnect levels, at least one of the interconnect levels comprising conductive shielding areas aligned with the photodetection areas.

2. The image sensor of claim 1, wherein the conductive shielding areas comprise a large conductive track formed aligned with the photodetection areas in an interconnect level.

3. The image sensor of claim 1, wherein the conductive shielding areas comprise a first assembly of parallel conductive tracks formed in a first interconnect level and a second assembly of parallel conductive tracks formed in a second interconnect level, the conductive tracks of the first and second assemblies being mutually perpendicular.

4. The image sensor of claim 1, further comprising, on the free side of the second substrate and on the vias, solder bumps.

5. The image sensor of claim 1, further comprising a glass plate formed on the first surface of the first substrate.

6. The image sensor of claim 5, wherein the first and second substrates are made of silicon and have a thickness ranging between 60 and 80 μm.

7. A method for forming a back-side illuminated image sensor, comprising the steps of:
forming, in and on a semiconductor substrate, photodetection elements topped with interconnect levels, each interconnect level comprising metal layers topped with insulating material;
forming, in at least one interconnect level, conductive shielding areas aligned with photodetection areas of the photodétection elements;
placing a second semiconductor substrate on the insulating material of the last interconnect level and thinning down the first substrate;
covering, with a glass plate, the first thinned-down substrate and thinning down the second substrate; and
forming vias in the second substrate.
